(19) United States
(12) Patent Application Publication
(10) Pub. No.: US 2005/0145923 A1
(43) Pub. Date: Jul. 7, 2005

(54) NAND flash memory with enhanced program and erase performance, and fabrication process

(76) Inventors: Chiou-Feng Chen, Santa Clara, CA (US); Prateep Tuntasood, Santa Clara, CA (US); Der-Tsyr Fan, Hsinchu (TW)

Correspondence Address: EDWARD S. WRIGHT, 1100 ALMA STREET, SUITE 207, MENLO PARK, CA, 94025, US

(21) Appl. No.: 10/753,103

(22) Filed: Jan. 6, 2004

(51) Int. Cl. H01L 21/82; H01L 29/788

(52) U.S. Cl. 257/315; 438/201; 257/390; 438/129

(57) ABSTRACT

NAND flash memory cell array and fabrication process in which control gates and floating gates are stacked in pairs arranged in rows between a bit line diffusion and a common source diffusion, with select gates on both sides of each of the pairs of stacked gates. The gates in each stacked pair are self-aligned with each other and

[symbol]

### BACKGROUND OF THE INVENTION

1. Field of Invention

This invention pertains generally to semiconductor memory devices and, more particularly, to a NAND flash memory and fabrication process.

2. Related Art

Nonvolatile memory is currently available in several forms, including electrically programmable read only memory (EPROM), electrically erasable programmable read only memory (EEPROM), and flash EEPROM. Flash memory has been widely used for high volume data storage in devices such as memory cards, personal digital assistants (PDA's), cellular phones, and MP3 players. Such applications require high density memory, with smaller cell size and reduced cost of manufacture.

The traditional NOR-type stack-gate flash memory cell usually has a bit line contact, a source region, a floating gate, and a control gate, with the control gate being positioned directly above the floating gate. Its relatively large cell size prevents it from being used in very high density data storage applications.

Cell size is smaller in a NAND flash memory array having a series of stack-gate flash memory cells connected in series between a bit-line and a source line, with only one bit-line contact, as illustrated in FIG. 1 and described in greater detail in U.S. Pat. Nos. 4,959,812 and 5,050,125. In this array, a plurality of stack-gate memory cells 21 are connected in series between a bit line 22 and a source line 23. The cells are formed in a P-well 24 in a substrate 26 of either N- or P-type silicon. Each of the cells has a floating gate 27 fabricated of a conductive material such as polysilicon and a control gate 28 fabricated of a conductive material such as polysilicon or polycide. The control gate is above and in vertical alignment with the floating gate.

Two select gates 29, 31 are included in the array, one near the bit line contact 32 and one near source diffusion 23. Diffusions 33 are formed in the substrate between the stacked gates and between the stacked gates and the select gates to serve as source and drain regions for the transistors in the memory cells. The bit line diffusion, source diffusion, and the diffusions 33 are doped with N-type dopants.

To erase the memory cell, a positive voltage of about 20 volts is applied between the P-well and the control gates, which causes the electrons to tunnel from the floating gates to the channel regions beneath them. The floating gates thus become positively charged, and the threshold voltage of the stack-gate cells becomes negative.

To program the memory cells, the control gates are biased to a level of about 20 volts positive relative to the P-well. As electrons tunnel from the channel region to the floating gates, the floating gates are negatively charged, and the threshold voltage of the stack-gate cells becomes positive. By changing the threshold voltage of a stack-gate cell, the channel beneath it can be in either a non-conduction state (logical “0”) or a conduction state (logical “1”) when a zero voltage is applied to the control gate during a read operation.

However, as the fabrication process advances to very smaller geometry, e.g., tens of nanometers, it is difficult to form a high-voltage coupling ratio which is sufficient for program and erase operations while maintaining a small cell size and meeting stringent reliability requirements such as 10 year data retention and 1,000,000 cycling operations between failures.

### OBJECTS AND SUMMARY OF THE INVENTION

It is in general an object of the invention to provide a new and improved semiconductor device and process for fabricating the same.

Another object of the invention is to provide a semiconductor device and process of the above character which overcome the limitations and disadvantages of the prior art.

These and other objects are achieved in accordance with the invention by providing a NAND flash memory cell array and fabrication process in which control gates and floating gates are stacked in pairs arranged in rows between a bit line diffusion and a common source diffusion, with select gates on both sides of each of the pairs of stacked gates. The gates in each stacked pair are self-aligned with each other and with the select gates adjacent to them. In one disclosed embodiment, the select gate at one end of each row partially overlaps the common source diffusion, and in another it lies directly above the source diffusion and is common to groups of cells on both sides of the diffusion.

The floating gates are surrounded by both the control gates and select gates, which forms a highly enhanced high-voltage coupling ratio for both the program and erase operations. With the enhanced high-voltage coupling ratio, the applied high voltages for program and erase operations can be reduced, and the tunnel oxide can also be maintained at a thicker thickness to achieve better, more reliable performance. The array is biased so that all of the memory cells in it can be erased simultaneously, while programming is bit selectable.

### BRIEF DESCRIPTION OF THE DRAWINGS

FIG. 1 is a cross-sectional view of a NAND flash memory array with a series of stack-gate flash memory cells of the prior art.

FIG. 2 is a cross-sectional view, taken along line 2-2 in FIG. 4, of one embodiment of a NAND flash memory cell array incorporating the invention.

FIG. 3 is a cross-sectional view, taken along line 3-3 in FIGS. 4 and 7, of the embodiments of NAND flash memory cell arrays incorporating the invention.

FIG. 4 is a top plan view of the embodiment of FIG. 2.

FIGS. 5A-5F are schematic cross-sectional views illustrating the steps in one embodiment of a process for fabricating a NAND flash memory cell array in accordance with the invention.

FIG. 6 is circuit diagram of a small memory array as in the embodiment of FIG. 2, showing exemplary bias conditions for erase, program and read operations.

FIG. 7 is a cross-sectional view, taken along line 7-7 in FIG. 8, of another embodiment of a NAND flash memory cell array incorporating the invention.

FIG. 8 is a top plan view of the embodiment of FIG. 7.

FIGS. 9A-9E are schematic cross-sectional views illustrating the steps in one embodiment of a process for fabricating the NAND flash memory cell array of FIG. 7.

FIG. 10 is circuit diagram of a small memory array as in the embodiment of FIG. 7, showing exemplary bias conditions for erase, program and read operations.

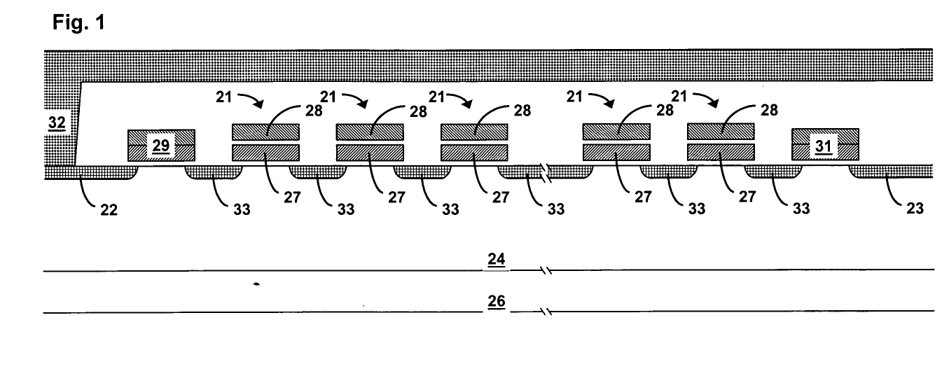

### DETAILED DESCRIPTION

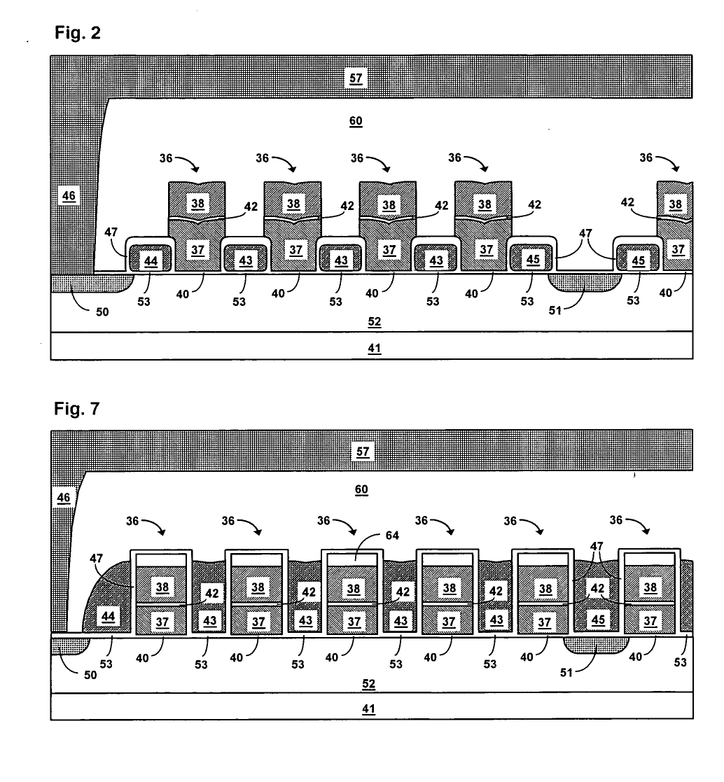

As illustrated in FIG. 2, the memory includes an array of stack-gate NAND flash memory cells 36, each of which has a floating gate 37 and a control gate 38 positioned above and in vertical alignment with the floating gate. A series or group of cells in one row of the array is positioned between a bit line diffusion 50 and a common source diffusion 51 which are formed in a P-type 52 well in the upper portion of a substrate 41 and doped with an N-type material.

The floating gates are fabricated of a conductive material such as polysilicon or amorphous silicon, with a preferred thickness on the order of 200 Å to 2000 Å. Dielectric films 47 are formed on the side walls of the floating gates, and gate insulators 40 are formed beneath them. The dielectric films can be a pure thermal oxide or a combination of thermal oxide, a CVD oxide and a CVD nitride, and the gate insulators are typically a thermal oxide.

The control gates are fabricated of a conductive material such as a doped polysilicon or polycide, and is insulated from the floating gates beneath them by dielectric films 42. Those films can be either a pure oxide or a combination of oxide, nitride and oxide (ONO), and in one presently preferred embodiment, they consist of a layer nitride between two layers of oxide.

Select gates 43 are positioned between stack-gate cells 36, and a select gate 44 is positioned between the cell at one end of the group and bit line contact 46. Another select gate 45 is positioned between the cell at the other end of the group and source diffusion 51. The select gates are fabricated of a conductive material such as a doped polysilicon or polycide. They are parallel to the control gates and the floating gates, and are separated from the floating gates by dielectric films 47.

The Select gates are separated from the substrate by gate oxide layers 53, which can be either a pure thermal oxide or a combination of thermal oxide and CVD oxide.

In this embodiment erase paths extend from the floating gates through tunnel oxides 40 to the channel regions of the silicon substrate between the floating gates and the select gates.

Select gates 44 and 45 partially overlap bit line diffusion 50 and common source diffusion 51, with edge portions of the two gates being positioned above edge portions of the diffusions. The diffusions extend continuously in a direction perpendicular to the rows in which the cells are grouped, and are shared by groups of cells on both sides of the diffusions.

As best seen in FIG. 4, isolation regions 56 are formed in the substrate between the floating gates in adjacent rows of cells, and control gates 38 extend in a direction parallel to the bit line and source diffusions, crossing over the floating gates and isolation regions. Bit lines 57 are positioned above the rows of cells, crossing over stacked gates 37, 38 and select gates 43, 44, 45, with contacts 46 extending between the bit lines and the bit line diffusions. The bit lines are thus perpendicular to the select gates and to the bit line and source diffusions.

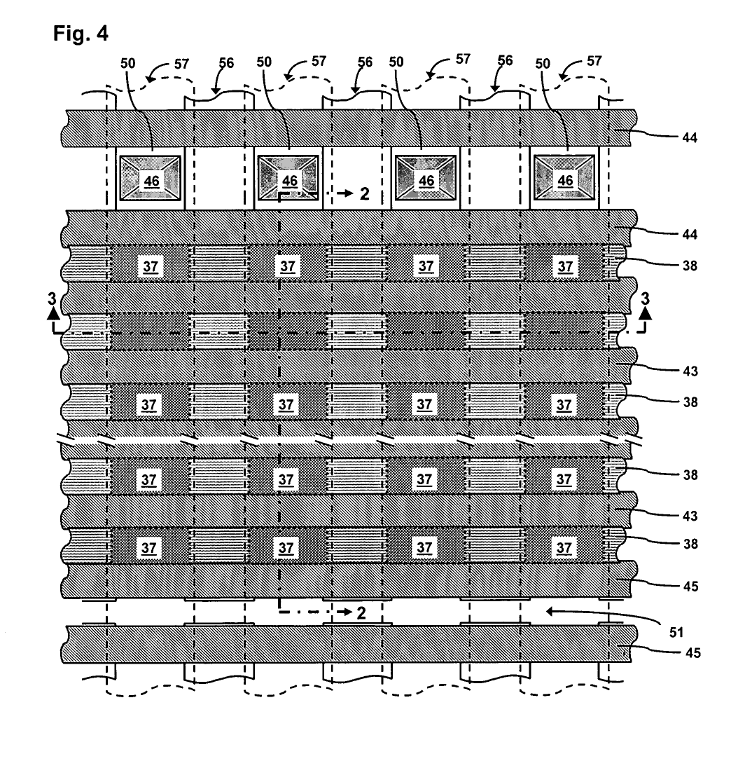

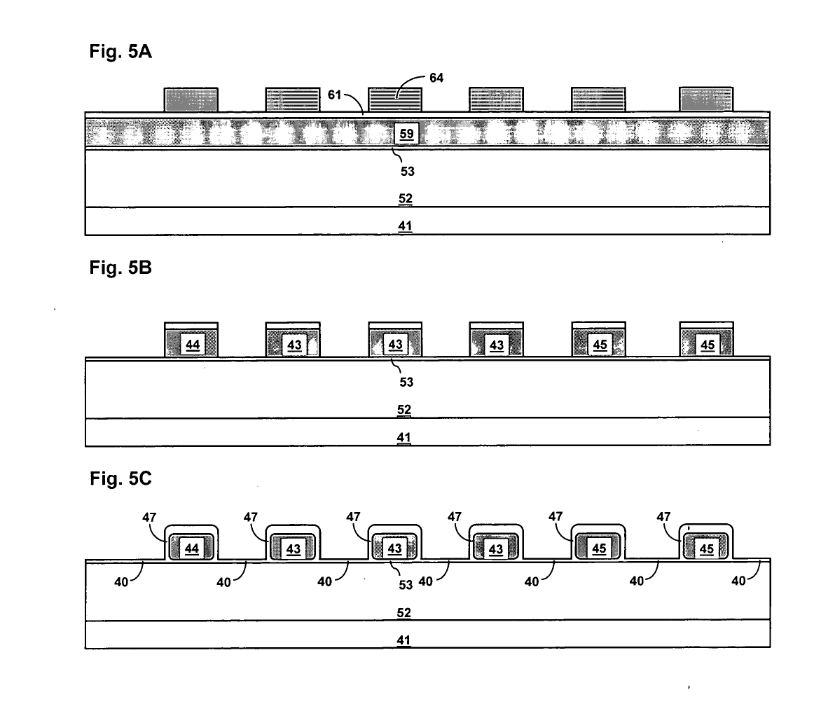

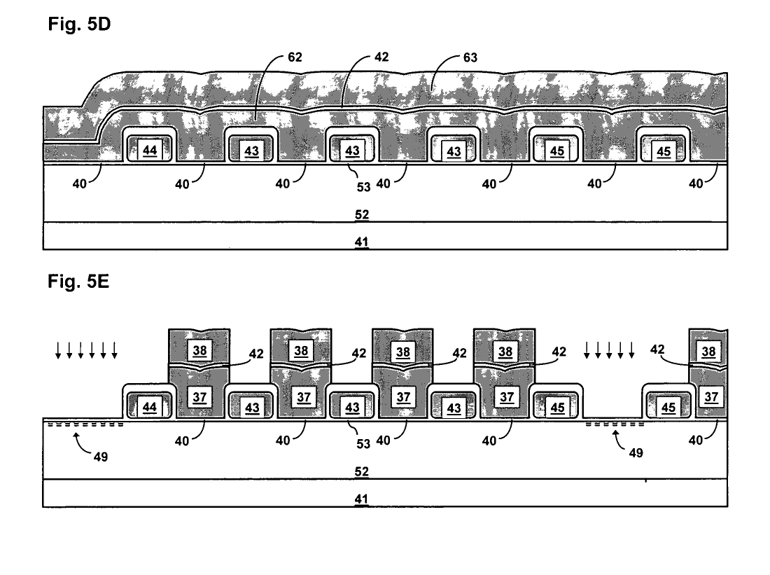

The memory cell array of FIGS. 2-4 can be fabricated by the process illustrated in FIGS. 5A-5F. In this process, an oxide layer 53 is thermally grown to a thickness of about 70 Å to 200 Å on a monocrystalline silicon substrate which, in the embodiment illustrated, is in the form of a P-type substrate 41 in which a P-type well 52 is formed. Alternatively, if desired, an N-type well can be formed in the P-type substrate, in which case the P-type well will be formed in the N-type well.

A conductive layer 59 of polysilicon (poly-1) is deposited on the thermal oxide to a thickness on the order of 300 Å to 1500 Å, and a dielectric layer 61 is formed on the silicon. This silicon is preferably doped with phosphorus, arsenic or boron to a level on the order of 10¹⁸ to 10²⁰ per cm³. The doping can be done in-situ during deposition of the silicon or by ion implantation directly into the silicon or through the dielectric 61 above it.

A photolithographic mask 64 is applied to dielectric layer 61 to define the select gates. The unmasked portions of the dielectric and silicon layers etched away anisotropically to form select gates 43, 44, 45, as illustrated in FIG. 5B. Then, as shown in FIG. 5C, a dielectric 47 is formed on the side walls of the select gates. This dielectric can be a pure oxide film or the combination of thermal oxide, CVD oxide and nitride films. Portions of the dielectric film 47 on the silicon surface are etched away anisotropically, and tunnel oxide 40 is grown on the silicon.

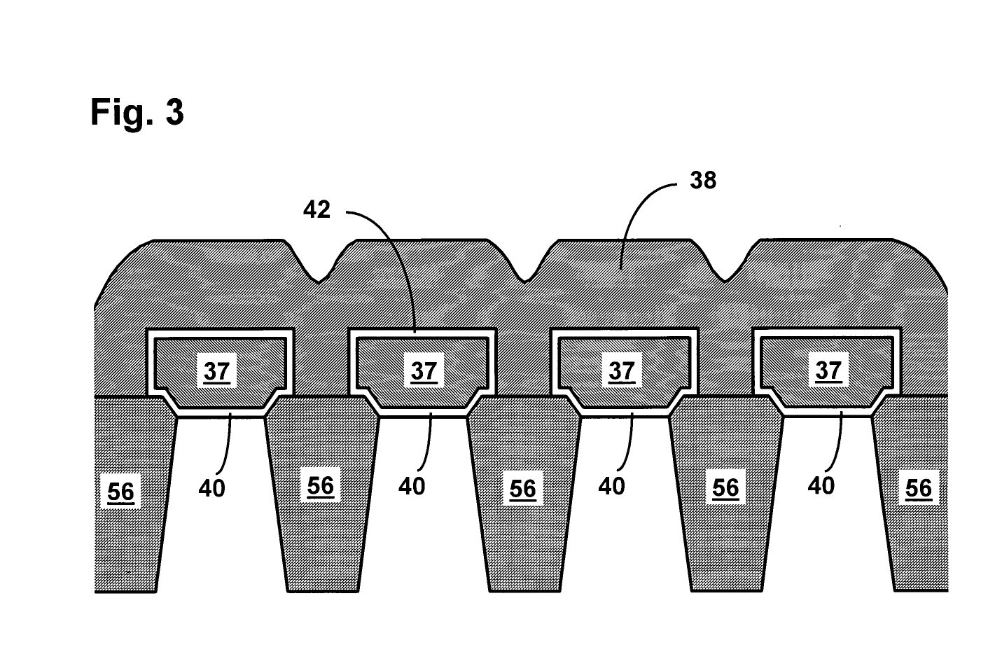

As illustrated in FIG. 5D, a conductive layer 62 of polysilicon or amorphous silicon (poly-2) is deposited on the thermal oxide to a thickness on the order of 300 Å to 2500 Å. The portions of the poly-2 above the select gates are etched away anisotropically, leaving strips of poly-2 above the active regions for use in forming the floating gates 37. As best seen in FIG. 3, these strips extend in the direction of the rows, i.e. between the bit line and common source diffusions.

An inter-poly dielectric layer 42 is then formed on the poly-2 strips. That silicon is preferably doped with phosphorus, arsenic or boron to a level on the order of 10¹⁷ to 10²⁰ per cm³. The doping can be done in-situ during deposition of the silicon or by ion implantation either directly into the silicon or through the dielectric 42 above it.

The inter-poly dielectric can be either a pure oxide or a combination of oxide, nitride and oxide (ONO), and in the embodiment illustrated, it consists of a lower oxide layer having a thickness on the order of 30-100 Å, a central nitride layer having a thickness on the order of 60-200 Å, and an upper oxide layer having a thickness on the order of 30-100 Å.

Another conductive layer 63 of polysilicon or polycide (poly-3) is deposited on dielectric film 42 to a thickness on the order of 1000 Å to 2500 Å and is doped with phosphorus, arsenic or boron to a level on the order of 10²⁰ to 10²¹ per cm³.

A photolithographic mask (not shown) then is formed over conductive layer 63 to define the control and floating gate stacks, and the unmasked portions of the poly-3 layer, inter-poly dielectric layer, and poly-2 layer are etched away anisotropically to form the control gates 38 and floating gates 37, as illustrated in FIG. 5E. Diffusion regions 49 are then formed in the substrate next to select gates 44, 45 by ion implantation with dopants such as P³¹ or As⁷⁵.

Thereafter, a glass material 60 such as phosphosilicate glass (PSG) or borophosphosilicate glass (BPSG) is deposited across the entire wafer, then etched to form openings for bit line contacts 46, as shown in FIG. 5F. Finally, a metal layer is deposited over the glass and patterned to form bit lines 57 and bit line contacts 46.

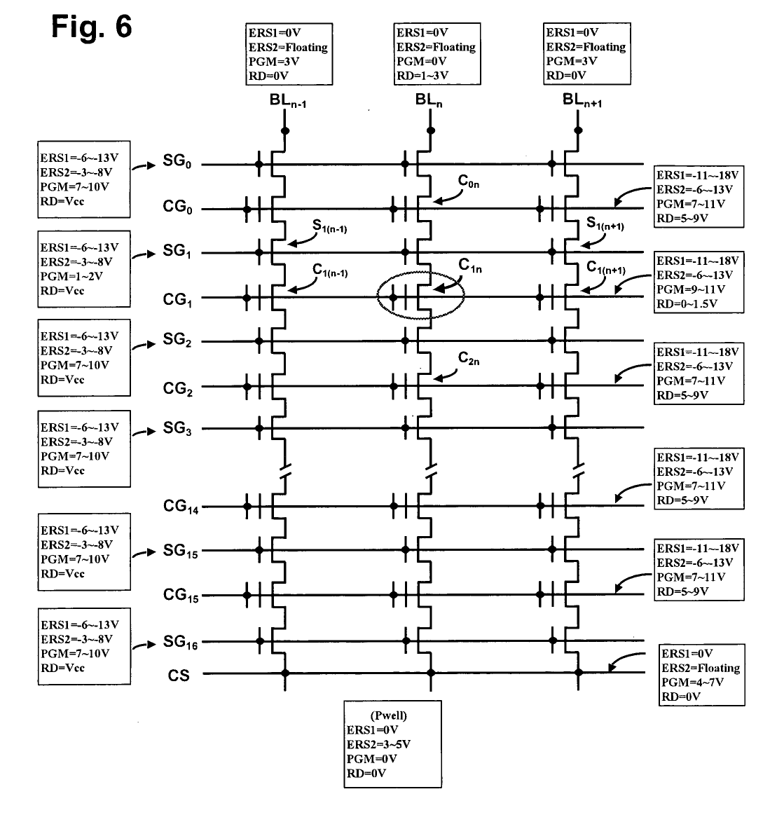

Operation and use of the memory cell array can be described with reference to FIG. 6 where exemplary bias voltages for erase (ERS), program (PGM) and read (RD) operations are shown next to the terminals of the array. In this example, memory cell C₁ₙ is selected. This cell is located at the intersection of control gate CG₁ and bit line BLₙ, and is encircled on the drawing for ease of location. All of the other memory cells in the array are unselected.

During an erase operation, electrons are forced to tunnel from the floating gate to the channel region beneath it, leaving positive ions in the majority with the floating gate. When the electric field across the tunnel oxide is more than about 10 mV/cm, Fowler-Nordheim tunneling becomes significant, and electrons with sufficient energy can tunnel from the cathode electrode (floating gate) to the anode electrode (channel region).

The floating gate is surrounded by and capacitively coupled to the control gate and the select gates, with the control gate above and on two sides of the floating gate and the select gates on the other two sides of the floating gate. With the floating gate surrounded in this manner, high-voltage coupling from the control and select gates to the floating gate is greatly enhanced. The voltage required for Fowler-Nordheim tunneling is thus reduced significantly, and the enhanced coupling also makes it possible to use a thicker tunnel oxide while still maintaining sufficient electron tunneling.

Erasing can be done using two different bias conditions. In erase mode 1 (ERS1), the control gate is biased at a level on the order of −11 to −18 volts, the select gates are biased at −6 to −13 volts, and the bit line, common source and P-well are biased at 0 volts. In erase mode 2 (ERS2), the control gate is biased at a level on the order of −6 to −13 volts, the select gates are biased at −3 to −8 volts, bit line and common source are floating, and the P-well is biased at 3 to 5 volts.

With these bias conditions, most of the voltage applied between the control gate and the select gates appears across the tunnel oxide beneath the floating gate. That triggers Fowler-Nordheim tunneling, with electrons tunneling from the floating gate to the channel region. As the floating gate becomes more positively charged, the threshold voltage of the memory cell, which is preferably on the order of −2 to −5 volts in this embodiment, becomes lower. This results in an inversion layer in the channel beneath the floating gate when the control gate is biased at 0-1.5 volts. Therefore, the memory cell goes into the conductive state (logic “1”) after the erase operation.

In the unselected memory cells, the control gates and the select gates are biased at 0 volts, so there is no Fowler-Nordheim tunneling during the erase operation.

During a program operation, the control gate of the selected memory cell C₁ₙ is biased to a level of 9-11 volts, 7-10 volts is applied to select gates SG₀ and SG₂-SG₁₆, 7-11 volts is applied to the control gates of the other memory cells in the same bit line direction as the selected cell (e.g. C₀ₙ and C₂ₙ), the bit line and P-well are held at 0 volts, and 4-7 volts is applied to the common source. The cells and the select transistors are turned on by applying 7-11 volts to the control gates and 7-10 volts to the select gates. The voltage applied to the select gate just before the selected cell (SG₁ and C₁ₙ in this example) can be on the low side, preferably on the order of 1-2 volts.

With these bias conditions, most of the voltage between the common source and the bit line appears across the mid-channel region between select gate SG₁ and the floating gate of the selected cell C₁ₙ, resulting in a high electric field in that region. In addition, since the floating gate is coupled to a high voltage from the common source node (i.e., control gate CG₁ and select gate SG₂), a strong vertical electric field is established across the oxide between the mid-channel region and the floating gate. When electrons flow from the bit line to the common source during the program operation, they are accelerated by the electric field across the mid-channel region, and some of them become heated. Some of the hot electrons get accelerated by the vertical field, which causes them to overcome the energy barrier of the oxide (about 3.1 eV) and inject into the floating gate.

At the end of the program operation, the floating gate is negatively charged, and the threshold voltage of the memory cell, which preferably is on the order of 2-4 volts, becomes higher. Thus, the memory cell is turned off when the control gate is biased at 0-1.5 volts during a read operation. Following a program operation, the memory cell goes into a non-conductive state (logic “0”).

In the unselected memory cells C₁₍ₙ₋₁₎ and C₁₍ₙ₊₁₎ which share the same control gate with the selected cell C₁ₙ, the bit line is biased at 3 volts, the select gate SG₁ is at 1-2 volts, and the control gate is at 9-11 volts. Thus, select transistors S₁₍ₙ₋₁₎ and S₁₍ₙ₊₁₎ are turned off, and there is no mid-channel hot carrier injection taking place in cells C₁₍ₙ₋₁₎ and C₁₍ₙ₊₁₎. The other unselected memory cells C₀ₙ and C₂ₙ are biased with 0 volts to the bit line, 7-11 volts to the control gates, and 7-10 volts to the select gates just before them, which minimizes the mid-channel hot carrier injection, and the floating gate charges are unchanged.

In the read mode, the control gate of the selected memory cell C₁ₙ is biased at 0-1.5 volts, the common source is biased to 0 volt, 1-3 volts is applied to the bit line, and Vcc is applied to the select gates. The unselected memory cells in the bit line direction, e.g. C₀ₙ and C₂ₙ, are turned on by applying 5-9 volts to their control gates. When the memory cell is erased, the read shows a conductive state because the channel of selected cell is turned on, and the other cells and the select transistors in the same bit line direction also turned on. Thus, a logic “1” is returned by the sense amplifier. When the memory cell is programmed, the read shows a non-conductive state because the channel of the selected cell is turned off, and hence the sense amplifier returns a logic “0”. In the unselected memory cells C₁₍ₙ₋₁₎ and C₁₍ₙ₊₁₎, both the bit line and common source nodes are biased at 0 volts, and there is no current flow between the bit line and the common source nodes.

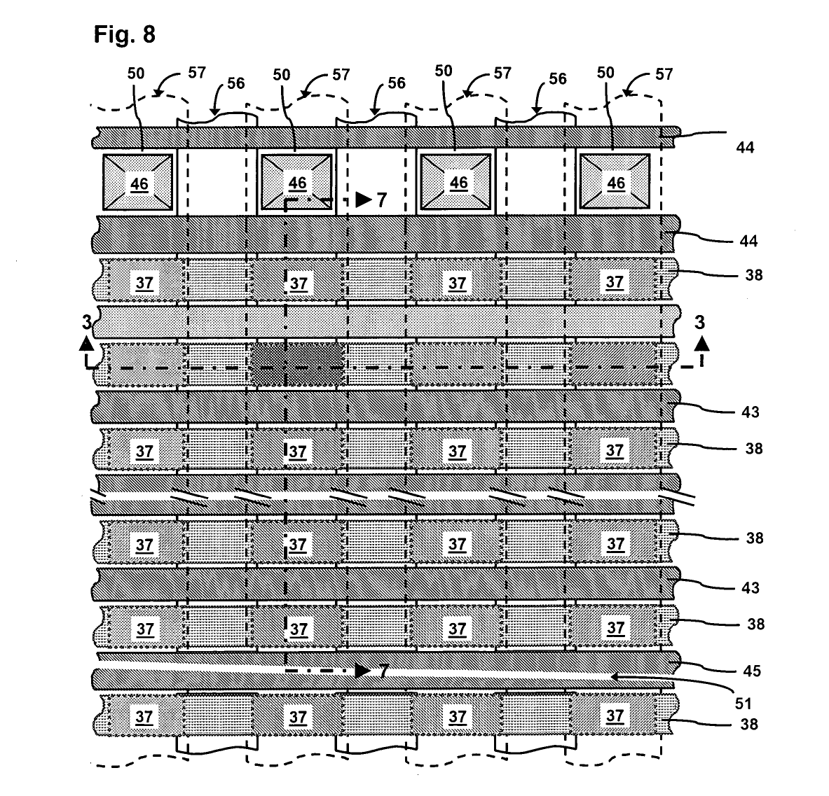

The embodiment of FIGS. 7-8 is generally similar to the embodiment of FIGS. 2-4, and like reference numerals designate corresponding elements in the two. In the embodiment of FIGS. 7-8, however, select gate 45 is positioned directly above source diffusion region 51 and is shared by the two groups of cells on opposite sides of it. The floating gates 37 adjacent to select gate 45 partially overlap the source diffusion.

As in the embodiment of FIGS. 2-4, control gates 38 cross over the floating gates 37 and isolation regions 56 in adjacent rows of cells, and select gates 43-45 extend in a direction perpendicular to the rows and parallel to the select gates. Bit lines 57 are perpendicular to the select and control gates, and cross over the bit line contact 46, select gates, and control gates 38 in each row of the array. The erase path once again extends from the floating gate through tunnel oxide 40 to the channel region below.

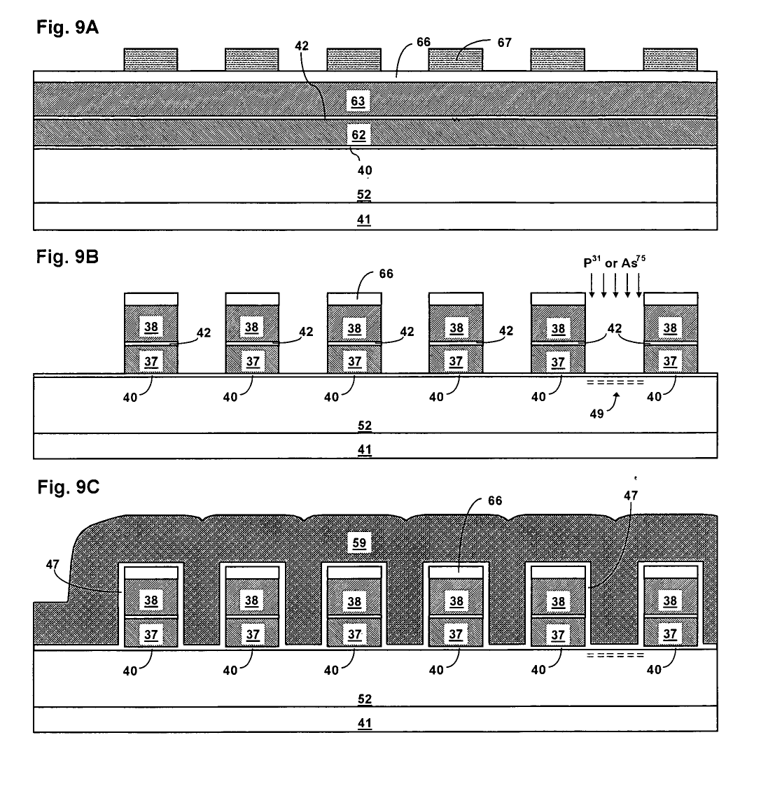

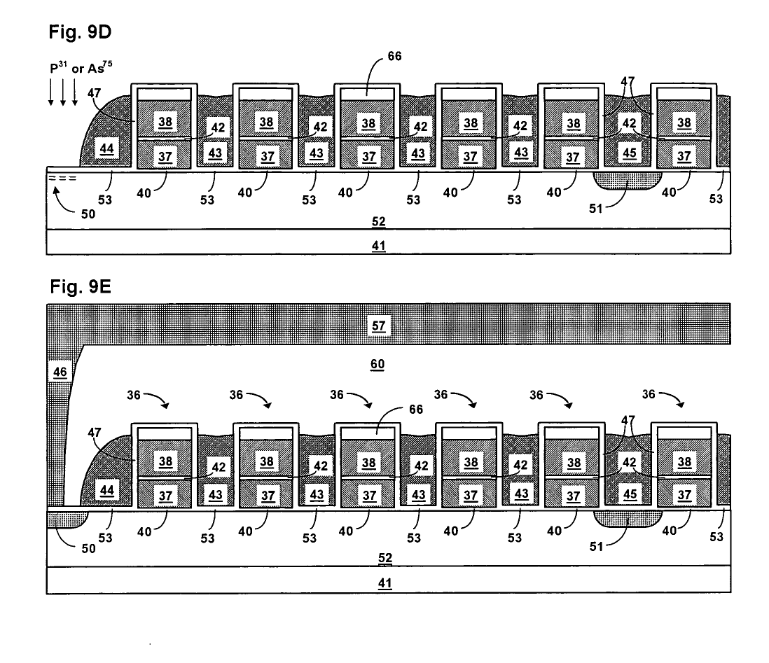

A preferred process of fabricating the embodiment of FIGS. 7-8 is illustrated in FIGS. 9A-9E. In this process, oxide layer 40 is thermally grown to a thickness of about 60 Å to 120 Å on a monocrystalline silicon substrate which, in the embodiment illustrated, is in the form of a P-type substrate 41 in which a P-type well 52 is formed. Alternatively, if desired, an N-type well can be formed in the P-type substrate, in which case the P-type well will be formed in the N-type well.

A conductive layer 62 of polysilicon or amorphous silicon (poly-1) is deposited on the thermal oxide to a thickness on the order of 300 Å to 1500 Å, and portions of it are then etched away anisotropically to form strips of silicon above the active regions for use in forming the floating gates 37. As in the previous embodiment and best seen in FIG. 3, these strips extend in the direction of the rows, i.e. between the bit line and common source diffusions.

An inter-poly dielectric layer 42 is formed on the poly-1 strips. That silicon is preferably doped with phosphorus, arsenic or boron to a level on the order of 10¹⁷ to 10²⁰ per cm³. The doping can be done in-situ during deposition of the silicon or by ion implantation either directly into the silicon or through the dielectric 42 above it. The inter-poly dielectric can be either a pure oxide or a combination of oxide, nitride and oxide (ONO), and in the embodiment illustrated, it consists of a lower oxide layer having a thickness on the order of 30 Å-100 Å, a central nitride layer having a thickness on the order of 60 Å-200 Å, and an upper oxide layer having a thickness on the order of 30 Å-100 Å.

A second layer 63 of polysilicon (poly-2) is deposited on dielectric film 42. This layer has a thickness on the order of 1500 Å-3500 Å, and is doped with phosphorus, arsenic or boron to a level on the order of 10²⁰ to 10²¹ per cm³. A CVD oxide or nitride layer 66 having a thickness on the order of 300 Å-1000 Å is deposited on the poly-2 layer, and is used as a mask to prevent the poly-2 material from etching away during subsequent dry etching steps.

A photolithographic mask 67 is formed over layer 66 to define the control gates, and the unmasked portions of that layer and poly-2 layer 63 are etched away anisotropically, leaving only the portions of the poly-2 which form the control gates 38. The exposed portions of the inter-poly dielectric 42 and the underlying portions of the poly-1 layer 62 are then etched away anisotropically to form the floating gates 37, as illustrated in FIG. 9B. Thereafter, diffusion region 49 is formed in the substrate between the stack gates by ion implantation using with dopants such as P³¹ or As⁷⁵.

Following ion implantation, a dielectric 47 is formed on the sidewalls of control and floating gates, and a conductive (poly-3) layer 62 is deposited over the entire wafer, as shown in FIG. 9C. The dielectric can be either a pure oxide or a combination of oxide, nitride and oxide (ONO), and in the embodiment illustrated, it consists of a lower oxide layer having a thickness on the order of 30 Å-100 Å, a central nitride layer having a thickness on the order of 60 Å-300 Å, and an upper oxide layer having a thickness on the order of 30 Å-100 Å. The poly-3 layer is typically doped polysilicon or polycide, and is deposited to a thickness on the order of 1500 Å-3000 Å.

The poly-3 layer is then etched anisotropically to form select gates 43, 44, 45, as illustrated in FIG. 9D. Being formed in this manner, the select gates are self-aligned and parallel to the control gates. N-type dopants such as P³¹ or As⁷⁵ are implanted into P-well 52 to form the bit line diffusion 50.

Thereafter, a glass material 60 such as phosphosilicate glass (PSG) or borophosphosilicate glass (BPSG) is deposited across the entire wafer, then etched to form openings for bit line contacts 46, as shown in FIG. 9E. Finally, a metal layer is deposited over the glass and patterned to form bit lines 57 and bit line contacts 46.

Operation of the embodiment of FIGS. 7 and 8 is generally similar to that of the embodiment of FIGS. 2-4. In this embodiment, however, select gate 45 is located above common source diffusion 51, and it is biased differently for program and read operations than in the previous embodiment.

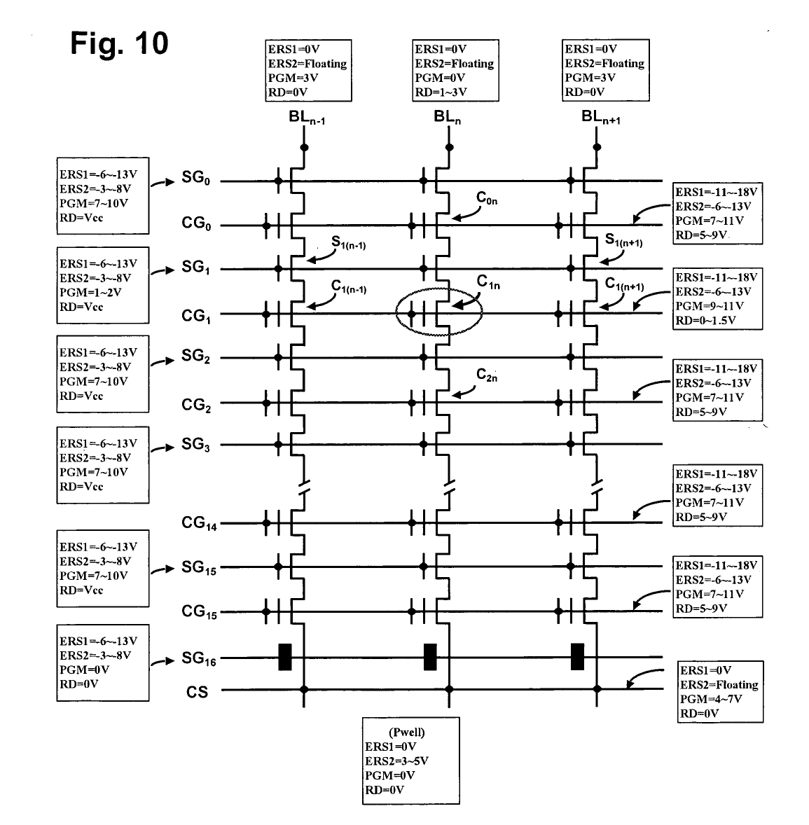

In FIG. 10, exemplary bias voltages for erase (ERS), program (PGM) and read (RD) operations are shown next to the terminals of the array. In this example, memory cell C₁ₙ is once again selected. This cell is located at the intersection of control gate CG₁ and bit line BLₙ, and is encircled on the drawing for ease of location. All of the other memory cells in the array are unselected.

During an erase operation, electrons are forced to tunnel from the floating gate to the channel region beneath it, leaving positive ions in the floating gate. When the electric field across the tunnel oxide is more than 10 mV/cm, Fowler-Nordheim tunneling becomes significant, and electrons with sufficient energy can tunnel from the floating gate to the channel region.

With the control gate and the select gates surrounding the floating gate or cathode electrode, high-voltage coupling from the control gate and select gates to the floating gate is once again substantially enhanced, and the voltage required for Fowler-Nordheim tunneling is reduced significantly. The enhanced coupling also makes it possible to use a thicker tunnel oxide while still maintaining sufficient electron tunneling.

Erasing can be done using two different bias conditions. In erase mode 1 (ERS1), the control gate is biased at a level on the order of −11 to −18 volts, the select gates are biased at −6 to −13 volts, and the bit line, common source and P-well are biased at 0 volts. In erase mode 2 (ERS2), the control gate is biased at a level on the order of −6 to −13 volts, the select gates are biased at −3 to −8 volts, bit line and common source are floating, and the P-well is biased at 3 to 5 volts.

With these bias conditions, most of the voltage applied between the control gate and the select gates appears across the tunnel oxide under the floating gate. That triggers Fowler-Nordheim tunneling, with electrons tunneling from the floating gate to the underneath channel region. As the floating gate becomes more positively charged, the threshold voltage of the memory cell, which is preferably on the order of −2 to −5 volts in this embodiment, becomes lower. This results in an inversion layer in the channel under the floating gate when the control gate is biased at 0 volts. Therefore, the memory cell goes into the conductive state (logic “1”) after the erase operation.

In the unselected memory cells, the control gates and the select gates are biased at 0 volts, so there is no Fowler-Nordheim tunneling during the erase operation.

During a program operation, the control gate of the selected memory cell C₁ₙ is biased to a level of 9-11 volts, 7-10 volts is applied to select gates SG₀ and SG₂-SG₁₅, 0 volts is applied to select gate SG₁₆, 7-11 volts is applied to the control gates of the other memory cells in the same bit line direction as the selected cell (e.g. C₀ₙ and C₂ₙ), the bit line and P-well are held at 0 volts, and 4-7 volts is applied to the common source. The cells and the select transistors are turned on by applying 7-11 volts to the control gates and 7-10 volts to the select gates. The voltage applied to the select gate just before the selected cell (SG₁ and C₁ₙ in this example) can be on the low side, preferably on the order of 1-2 volts.

With these bias conditions, most of the voltage between the common source and the bit line appears across the mid-channel region between select gate SG₁ and the floating gate of the selected cell C₁ₙ, resulting in a high electric field in that region. In addition, since the floating gate is coupled to a high voltage from the common source node (i.e., control gate CG₁ and select gate SG₂), a strong vertical electric field is established across the oxide between the mid-channel region and the floating gate. When electrons flow from the bit line to the common source during the program operation, they are accelerated by the electric field across the mid-channel region, and some of them become heated. Some of the hot electrons get accelerated by the vertical field, which causes them to overcome the energy barrier of the oxide (about 3.1 eV) and inject into the floating gate.

At the end of the program operation, the floating gate is negatively charged, and the threshold voltage of the memory cell, which preferably is on the order of 2-4 volts, becomes higher. Thus, the memory cell is turned off when the control gate is biased at 0 volts during a read operation. Following a program operation, the memory cell goes into a non-conductive state (logic “0”).

In the unselected memory cells C₁₍ₙ₋₁₎ and C₁₍ₙ₊₁₎ which share the same control gate with the selected cell C₁ₙ, the bit line is biased at 3 volts, the select gate SG₁ is at 1-2 volts, and the control gate is at 9-11 volts. Thus, select transistors S₁₍ₙ₋₁₎ and S₁₍ₙ₊₁₎ are turned off, and there is no mid-channel hot carrier injection taking place in cells C₁₍ₙ₋₁₎ and C₁₍ₙ₊₁₎. The other unselected memory cells C₀ₙ and C₂ₙ are biased with 0 volts to the bit line, 7-11 volts to the control gates, and 7-10 volts to the select gates just before them, which minimizes the mid-channel hot carrier injection, and the floating gate charges are unchanged.

In the read mode, the control gate of the selected memory cell C₁ₙ is biased at 0-1.5 volts, the common source is biased to 0 volt, 1-3 volts is applied to the bit line, Vcc is applied to the select gates SG₀-SG₁₅, and 0 volts is applied to the select gate SG₁₆. The unselected memory cells in the bit line direction, e.g. C₀ₙ and C₂ₙ, are turned on by applying 5-9 volts to their control gates. When the memory cell is erased, the read shows a conductive state because the channel of selected cell is turned on, and the other cells and the select transistors in the same bit line direction also turned on. Thus, a logic “1” is returned by the sense amplifier. When the memory cell is programmed, the read shows a non-conductive state because the channel of the selected cell is turned off, and hence the sense amplifier returns a logic “0”. In the unselected memory cells C₁₍ₙ₋₁₎ and C₁₍ₙ₊₁₎, both the bit line and common source nodes are biased at 0 volts, and there is no current flow between the bit line and the common source nodes.

The invention has a number of important features and advantages. It provides a NAND flash memory cell array with significantly smaller cell size and greater cell density than memory structures heretofore provided. It also has enhanced high-voltage coupling for both program and erase operations, which means that the high voltage can be lower and the tunnel oxide beneath the floating gates can be thicker. The array is biased so that all of the memory cells in it can be erased simultaneously, while programming is bit selectable.

It is apparent from the foregoing that a new and improved NAND flash memory and process of fabrication have been provided. While only certain presently preferred embodiments have been described in detail, as will be apparent to those familiar with the art, certain changes and modifications can be made without departing from the scope of the invention as defined by the following claims.

1. A NAND flash memory cell array, comprising: a substrate having an active area, a plurality of vertically stacked pairs of floating gates and control gates arranged in rows above the active area, with the control gates being positioned above the floating gates, select gates aligned with and positioned on both sides of each of the stacked gates, a bit line above each row, a bit line diffusion in the active area toward a first end of each row, a bit line contact interconnecting the bit line in each row and the bit line diffusion, and a source region in the active area at least partially overlapped by the select gate at a second end of each row.

2. The memory cell array of claim 1 wherein stacked gates and the stacked gates are self-aligned relative to each other.

3. The memory cell array of claim 1 including a relatively thin tunnel oxide between the floating gates and the substrate, a first relatively thick dielectric between the floating gates and the select gates, and a second relatively thick dielectric between floating gates and control gates.

4. The memory cell array of claim 1 wherein the control gates and the select gates surround the floating gates in a manner which provides a relatively large inter-gate capacitance for high-voltage coupling during program and erase operations.

5. The memory cell array of claim 1 wherein erase paths extend from the floating gates, through the tunnel oxide to the channel regions, and high voltage is coupled to the floating gates both from the control gates and from the select gates.

6. The memory cell array of claim 1 wherein program paths extend from off-gate channel regions between the select gates and the floating gates to the floating gates, and high voltage is coupled to the floating gates both from the control gates and from the select gates on the sides of the stacked gates toward the source region.

7. The memory cell array of claim 1 wherein program paths extend from off-gate channel regions between the select gates and the floating gates to the floating gates, and the select gate on the bit line side of the stacked gates in a selected cell is biased at a lower voltage than the other select gates in the row to control channel current for efficient hot carrier injection during a program operation.

8. The memory cell array of claim 1 wherein the select gates in unselected cells are biased at a relatively high voltage to turn on the channels beneath them to form a conduction path between the bit line diffusion and the source diffusion.

9. The memory cell array of claim 1 wherein the bit line for a row containing a selected cell to be programmed is held at 0 volts, a relatively low positive voltage is applied to a cell select gate for the selected cell, a relatively high positive voltage is applied to the source diffusion at the second end of the row in which the selected cell is located, a relatively high positive voltage is applied to the control gate in the selected cell, a relatively high positive voltage is applied to the select gates for unselected cells, and a relatively high positive voltage is applied to the control gates in the unselected cells.

10. The memory cell array of claim 1 wherein an erase path is formed by a relatively high negative voltage on the control gates and a relatively low negative voltage on the select gates, with the bit line diffusions, the source diffusion and the P-well at 0 volts.

11. The memory cell array of claim 1 wherein an erase path is formed by a relatively high negative voltage on the control gates, and relatively low negative voltage on the select gates, with the P-well at a positive voltage and the bit line and source diffusions floating.

12. The memory cell array of claim 1 wherein a read path is formed by turning on the select transistors and the stacked control and floating gate transistors in unselected cells, with the common source at 0 volts, the bit line diffusion at 1-3 volts, and the control gate at relatively high positive voltage, and the control gate of the selected cell is biased at 0-1.5 volts to form a conduction channel under the floating gate for an erase state and a non-conduction channel for a program state.

13. The memory cell array of claim 1 including an erase path which can erase the whole cell array simultaneously and a program path which is single cell selectable.

14. In a process of fabricating a NAND flash memory cell array, the steps of: forming an oxide layer on an active area in a silicon substrate, forming a first silicon layer on the oxide layer, forming a dielectric film on the first silicon layer, etching away a portion of the dielectric film and the first silicon layer to form a row of select gates with exposed side walls, forming a first dielectric layer on the side walls of the select gates, forming a second silicon layer on the first dielectric layer, forming a second dielectric layer on the second silicon layer, forming a third silicon layer on the second dielectric layer, etching away portions of the third silicon layer to form control gates, etching away portions of the second silicon layer and the second dielectric layer to form floating gates which are thereby self-aligned with the control gates, forming bit line and source diffusions in the active area of the substrate between the select gates, and forming a bit line above the row and a bit line contact which interconnects the bit line and the bit line diffusion.

15. A NAND flash memory cell array, comprising: a substrate having an active area, a plurality of vertically stacked pairs of floating gates and control gates arranged in rows above the active area, with the control gates being positioned above the floating gates, select gates aligned with and positioned on both sides of each of the stacked gates, a bit line diffusion in the active area toward a first end of each row, a source diffusion in the active area directly beneath the select gate at a second end of each row, a bit line above each row, a bit line contact interconnecting the bit line in each row and the bit line diffusion.

16. The memory cell array of claim 15 wherein the select gates are self-aligned to the stacked control and floating gates.

17. The memory cell array of claim 15 including a relatively thin tunnel oxide between the floating gates and the substrate, a first relatively thick dielectric between the floating gates and the select gates, and a second relatively thick dielectric between floating gates and control gates.

18. The memory cell array of claim 15 wherein the control gates and the select gates surround the floating gates in a manner which provides a relatively large inter-gate capacitance for high-voltage coupling during program and erase operations.

19. A NAND flash memory cell array, comprising: a substrate having an active area, a plurality of vertically stacked pairs of floating gates and control gates arranged in rows above the active area, with the control gates being positioned above the floating gates, select gates aligned with and positioned on both sides of each of the stacked gates, a bit line above each row, a bit line diffusion in the active area toward a first end of each row, a bit line contact interconnecting the bit line in each row and the bit line diffusion, and a source region in the active area which is only partially overlapped by the select gate at a second end of each row.

20. The memory cell array of claim 19 wherein the each of the floating gates and the control gate above it are self-aligned with respect to each other.

21. The memory cell array of claim 19 including a relatively thin tunnel oxide between the floating gates and the substrate, a first relatively thick dielectric between the floating gates and the select gates, and a second relatively thick dielectric between floating gates and control gates.

22. The memory cell array of claim 19 wherein the control gates and the select gates surround the floating gates in a manner which provides a relatively large inter-gate capacitance for high-voltage coupling during program and erase operations.

23. A process of fabricating a NAND flash memory cell array, comprising the steps of: forming an oxide layer on an active area in a silicon substrate, forming a first silicon layer on the oxide layer, etching away portions of the first silicon layer to form a strip of silicon which extends above the active area and in the direction of the row, forming a first dielectric film on the first silicon layer, forming a second silicon layer on the first dielectric film, forming a second dielectric film on the second silicon layer, etching away portions of the second silicon layer and the second dielectric film to form a row of control gates with exposed side walls, etching away portions of the first silicon layer and the first dielectric film to form floating gates which are stacked beneath and self-aligned with control gates, forming a source diffusion in the active area of the substrate next to the stacked gates at one end of the row, forming a third dielectric film on the side walls of the control and floating gates, depositing a third silicon layer over the third dielectric film, removing portions of the third silicon layer to form select gates on both sides of each of the stacked gates, with the select gate at the one end of the row being positioned directly above the source diffusion, forming a bit line diffusion in the active area of the substrate near the select gate at the other end of the row, and forming a bit line above the row and a bit line contact which interconnects the bit line and the bit line diffusion.
